(19) United States
(12) Patent Application Publication
(10) Pub. No.: US 2022/0082668 A1
(43) Pub. Date: Mar. 17, 2022

(54) LIGHT DETECTOR AND DISTANCE MEASUREMENT DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Hiroshi KUBOTA, Yokohama Kanagawa (JP); Nobu MATSUMOTO, Ebina Kanagawa (JP); Masanori KATO, Ichikawa Chiba (JP); Mitsuhiro SENGOKU, Ota Tokyo (JP)

(21) Appl. No.: 17/187,313

(22) Filed: Feb. 26, 2021

(30) Foreign Application Priority Data
Sep. 17, 2020 (JP) 2020-156086

(51) Int. Cl. G01S 7/4863; G01S 17/26

(52) U.S. Cl. CPC G01S 7/4863; H01L 31/02019; G01S 17/26

(57) ABSTRACT

A light detector includes an array of single-photon avalanche photodiodes (SPADs). Each of the SPADs includes an avalanche photodiode (APD), a first resistor connected in series with the APD, a second resistor connected to a node between the APD and the first resistor, a rectifying element connected in series with the second resistor between the second resistor and a constant power source, and a high-frequency current reduction circuit connected in series with the rectifying element between the rectifying element and the constant power source. The high frequency current reduction circuit is configured to reduce a high-frequency current flowing toward the constant power source when an avalanche phenomenon occurs in the APD.

### CROSS-REFERENCE TO RELATED APPLICATION(S)

This application is based upon and claims the benefit of priority from Japanese Patent Application No. 2020-156086, filed Sep. 17, 2020, the entire contents of which are incorporated herein by reference.

### FIELD

Embodiments described herein relate generally to a light detector and a distance measurement device.

### BACKGROUND

A light detection and ranging (LiDAR) component of a distance measurement system irradiates a measurement target object with a laser, causes a sensor to detect the intensity of light reflected from the measurement target object, detects, based on an output of the sensor, when the reflected light arrives, and measures the distance to the measurement target object based on a difference between when the reflected light is detected and a when the laser was emitted towards the measurement target object.

This LiDAR technique is expected to be applied to in-vehicle devices such as sensors for autonomous driving. LiDAR can be used to measure a distance over a relatively long distance (e.g., several hundred meters or more), and thus requires a highly sensitive light sensor. For the sensitive light sensor, a photomultiplier that can detect even a single photon may be used. As a photomultiplier, a silicon photomultiplier (hereinafter it is referred to as a SiPM) may be used.

Furthermore, high resolution is also required for the LiDAR, and a multi-pixel SiPM having a one-dimensional (linear) or two-dimensional array configuration has been proposed.

Although a SiPM has high sensitivity, recovery after the light detection may take time. As a method of addressing this problem, an active quenching technique using an active element has been proposed in the related art.

### BRIEF DESCRIPTION OF THE DRAWINGS

FIG. 1 is a schematic configuration block diagram of a distance measurement device including a light detector according to an embodiment.

FIG. 2 is a schematic diagram of an example of a scanner and optical system.

FIG. 3 is a schematic diagram of a laser emission direction in the optical system in FIG. 2.

FIG. 4 is a diagram to explain a problem to be solved in the embodiment.

FIG. 5 depicts aspects related to a first embodiment.

FIG. 6 illustrates a plan view of a part of an array of SPADs.

FIG. 7 illustrates a cross-sectional view of the part of an array of SPADs.

FIG. 8 illustrates another cross-sectional view of a diode in a cross-section perpendicular to the cross section illustrated in FIG. 7.

FIGS. 9A and 9B illustrate a change in a cathode voltage of an avalanche photodiode.

FIGS. 10A and 10B illustrate a measurement result of a residual output.

FIGS. 11A and 11B illustrate a quantity of relative incident light and an output voltage of a SPAD.

FIG. 12 depicts aspects of a first modification example.

FIG. 13 depicts aspects of a second modification example.

FIG. 14 is a partial plan view of a SiPM of a second modification example.

FIG. 15 depicts aspects of a third modification example.

FIG. 16 depicts aspects of a first configuration example of a delay circuit.

FIG. 17 depicts aspects of a second configuration example of the delay circuit.

FIG. 18 depicts aspects related to a second embodiment.

FIG. 19 illustrates a cross-sectional view of a light detector according to a first modification example of a second embodiment.

FIG. 20 is a circuit diagram of a high-frequency current cut off circuit in a light detector according to a second modification example of a second embodiment.

FIG. 21 illustrates a profile of a residual output in a second modification example of a second embodiment.

FIG. 22 is a circuit diagram of a high-frequency current cut off circuit in a light detector according to a third modification example of a second embodiment.

### DETAILED DESCRIPTION

As described above, in a SiPM used for LiDAR, it is desirable to detect a small quantity of light from a long distance, but at the same time, it is desired that abnormal operation does not occur if a relatively large quantity of light is input.

Specifically, it is desirable to reduce the influence of a residual output generated when a quantity of electrons (FP) generated by light reception is in the following state with respect to a quantity of electrons (Gain) generated by avalanche breakdown:

FP<<Gain

When a relatively large quantity of light is incident on the SiPM, the problem that the residual output still exists even after several microseconds (μs) after the light reception is called the “memory effect.” (See A. Dalla Mora, A. Tosi, D. Contini, L. Di Sieno, G. Boso, F. Villa, and A. Pifferi, “Memory effect in silicon time-gated single-photon avalanche diodes”, JOURNAL OF APPLIED PHYSICS 117, 114501 (2015)).

Embodiment provide a light detector and a distance measurement device capable of reducing the influence of a residual output and continuing measurement at a predetermined period even after a relatively large quantity of light is received.

In general, according to an embodiment, a light detector includes an array of single-photon avalanche photodiodes (SPADs). Each of the SPADs includes an avalanche photodiode (APD), a first resistor connected in series with the APD, a second resistor connected to a node between the APD and the first resistor, a rectifying element connected in series with the second resistor between the second resistor and a constant power source, and a high-frequency current reduction circuit connected in series with the rectifying element between the rectifying element and the constant power source. The high frequency current reduction circuit is configured to reduce a high-frequency current flowing toward the constant power source when an avalanche phenomenon occurs in the APD.

Next, certain example embodiments will be described with reference to the drawings.

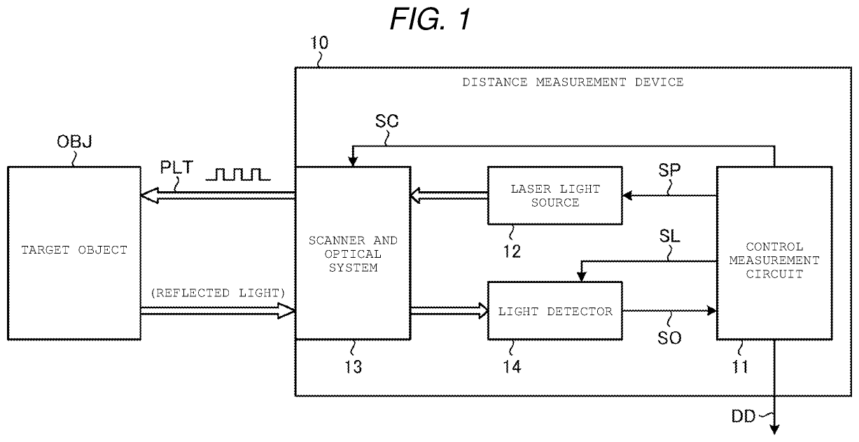

FIG. 1 is a schematic configuration block diagram of a distance measurement device including a light detector according to an embodiment.

A distance measurement device 10 is configured as a LiDAR that measures a distance by using a silicon photomultiplier (SiPM).

The distance measurement device 10 is configured to be capable of measuring a distance between the distance measurement device 10 and a distance measurement target object OBJ by using laser light as a measurement light. The distance measurement device 10 is configured as, for example, an in-vehicle LiDAR. In this case, the distance measurement target object OBJ is, for example, a tangible object such as another vehicle, a pedestrian, or an obstacle existing in front of, beside, or behind the vehicle on which the distance measurement device 10 is mounted.

The distance measurement device 10 includes a control measurement circuit 11, a laser light source 12, a scanner and optical system 13, and a light detector 14.

The control measurement circuit 11 controls an operation of the entire distance measurement device 10. More specifically, the control measurement circuit 11 transmits an oscillation signal SP to the laser light source 12 to control the emission of pulsed laser light PLT made by the laser light source 12. Further, the control measurement circuit 11 transmits a scan control signal SC to the scanner and optical system 13 to drive the scanner and optical system 13 and controls a scanning direction of the laser with which the target object OBJ is irradiated. The control measurement circuit 11 transmits a selection signal SL to the light detector 14 to select channels (a plurality of SiPMs) that detect light (including reflected light of the pulsed laser light PLT) received by the light detector 14. Further, when an output signal SO is input as a detection result of the light from the light detector 14, the control measurement circuit 11 calculates a distance between the distance measurement device 10 and the distance measurement target object OBJ based on the output signal SO and outputs distance data DD that includes the calculated distance.

The laser light source 12 emits the pulsed laser light PLT (e.g., infrared light) having a predetermined pulse width and period based on the oscillation signal SP from the control measurement circuit 11 and outputs the pulsed laser light PLT to the scanner and optical system 13.

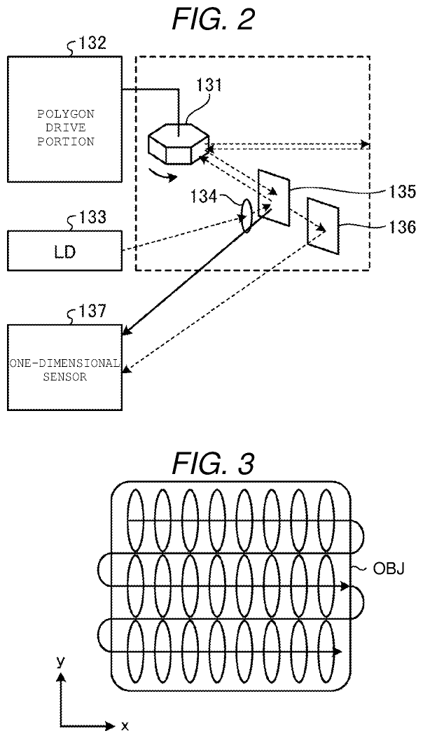

FIG. 2 is a schematic diagram of an example of a scanner and optical system.

In the optical system illustrated in FIG. 2, optical axes of projection light and reflected light are aligned by a pinhole (perforated) mirror or the like, and it is called a coaxial optical system.

The scanner and optical system 13 in FIG. 2 include, for example, a scanner, a light projection optical system, and a light receiving optical system.

In the example in FIG. 2, the scanner and optical system 13 includes a scanner portion, which includes a polygon mirror 131 in which each mirror surface has a different tilt angle and a polygon drive portion 132 that rotationally drives the polygon mirror 131, a lens 134 that collimates the laser emitted by the laser diode 133, a light projection optical system in which a collimated laser passes through a pinhole of a pinhole mirror 135 and projects the laser onto a scanning target object via the polygon mirror 131, and a light receiving optical system, which includes a polygon mirror 131 that receives the laser light reflected by the scanning target object, a mirror 136 that reflects the received laser light, and a one-dimensional sensor 137 that receives the laser reflected by the mirror 136.

By driving the scanner based on the scan control signal SC from the control measurement circuit 11, the scanner and optical system 13 is configured to be capable of changing the emission direction of the laser emitted to the outside of the distance measurement device 10 via the light projection optical system. More specifically, for example, the scanner and optical system 13 includes a one-dimensional scanning system (for example, it scans in the horizontal direction), and is configured to be capable of emitting the laser comprehensively with respect to a predetermined two-dimensional range by repeating the laser scanning (for example, in a slightly different direction for the vertical direction) by the one-dimensional scanning system a plurality of times.

FIG. 3 is a schematic diagram of a laser emission direction in the optical system in FIG. 2.

As illustrated in FIG. 3, when the scanning target object is scanned by the laser in the x direction and the laser reaches from one end (the left side in the figure) to the other end (the right side in the figure) of the scanning target object, this time, a location shifted by a predetermined distance in the y direction is operated from the other end (the right side in the figure) to the one end (the left side in the figure) of the scanning target object, and thereafter, the same procedure is repeated to scan a predetermined two-dimensional range.

The scanner that constitutes the scanner and optical system 13 may be configured such that the laser is scannable by rotating a stage on which the light projection optical system is mounted, or configured such that the laser is scannable by swinging (swiveling) the mirror of the light projection optical system.

Further, the light receiving optical system that constitutes the scanner and optical system 13 condenses the received light (which generally includes environmental light or stray light in addition to the reflected light), which includes the reflected light of the emitted pulsed laser light PLT reflected from the target object 2 back to the light detector 14. The environmental light or stray light corresponds to noise.

When the received light is incident from the scanner and optical system 13, for example, the light detector 14 generates electrons in accordance with the number of photons contained in the reflected light for each period of the pulsed laser light PLT emitted by the laser light source 12. The light detector 14 is configured to be capable of generating, for example, substantially 100,000 times as many electrons from each photon. The light detector 14 generates an output signal SO in accordance with the number of generated electrons and outputs the output signal SO to the control measurement circuit 11. In the optical system in FIG. 2, basically the same location is irradiated with the reflected light regardless of the scanning direction. As illustrated in FIG. 3, the projection light has an elongated shape in one direction (for example, a vertical direction), and a one-dimensional sensor, in which a plurality of pixels are arranged along one direction, can be used. A plurality of individual sensors may be used instead of the one-dimensional sensor. Furthermore, the above optical system is an example, and a non-coaxial optical system may be adopted instead of the coaxial optical system, and a two-dimensional sensor may be used.

A problem to be solved by an embodiment will be described.

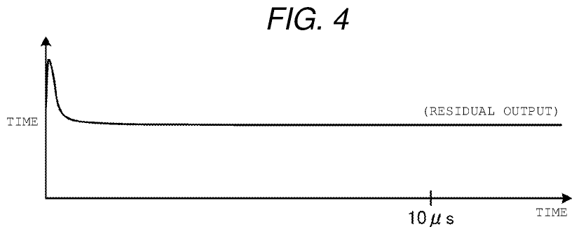

FIG. 4 is a diagram to explain a problem to be solved in the embodiment.

When a relatively large quantity of light is incident on the SiPM, the distance measurement device 10 configured as the LiDAR exceeds a measurement interval of the LiDAR (for example, up to 10 μs) as illustrated in FIG. 4, and the residual output remains, which gives influence to the next measurement.

Such a situation occurs when the quantity of electrons (FP) generated by the light reception is in the following state with respect to the quantity of electrons (Gain) generated by avalanche breakdown:

FP<<Gain

The above state is different from a state in which when a very large quantity of light is incident on the SiPM, it takes a long time to release an electric charge through a quenching resistor accumulated in the avalanche photodiode, and the SiPM cannot be used for a long time.

That is, such a situation occurs when the quantity of electrons (FP) generated by the light reception is in the following state with respect to the quantity of electrons (Gain) generated by the avalanche breakdown:

FP≥Gain

In order to avoid such a situation, in the SPAD, a configuration is proposed in which a resistive element and a rectifying element (diode) are connected to each other in parallel with the quenching resistor, but in order to eliminate the influence on the characteristics of the SiPM, it is necessary to set the potential of the anode of the diode as a rectifying element (=potential of out2) lower than the breakdown voltage Vbd+Vth. Wherein, Vth is a threshold value of the diode. The voltage drop of the cathode potential of the SPAD exceeds the breakdown voltage Vbd and overshoots only the voltage Vov2.

In order to avoid influence on the characteristics of the SiPM, it is necessary to set the potential lower than the voltage+Vth=Vbd+Vth−Vov2 at which the electron avalanche stops in the avalanche photodiode.

For that reason, the configuration in which the resistive element and the rectifying element (e.g., a diode) are connected to each other in parallel with the quenching resistor does not properly operate when:

FP<<Gain

Therefore, such a configuration is not a configuration that can avoid the influence of the residual output.

When the potential of the anode of the diode as a rectifying element (=potential of out2) is set higher than Vbd+Vth−Vov2, a current flows to the diode side as the rectifying element when the avalanche phenomenon generated in the avalanche photodiode occurs, and since the voltage drop in the quenching resistor is reduced, it becomes difficult to stop the avalanche phenomenon, the avalanche current increases, and then the crosstalk noise also increases.

Further, when the SPAD is arranged two-dimensionally, for example, it is conceivable to arrange the SPAD so as to electrically separate the central area of the 3×3 SPAD arrangeable area by wells and provide an area in which the rectifying elements for the periphery of the eight SPADs are arranged together.

In this case, since it is necessary to arrange the area for providing the rectifying element, light cannot be detected in that area, resulting in a so-called blind spot. Further, since the actual number of arranged SPADs is reduced, there is a problem that the sensitivity and the dynamic range are lowered.

### [1] First Embodiment

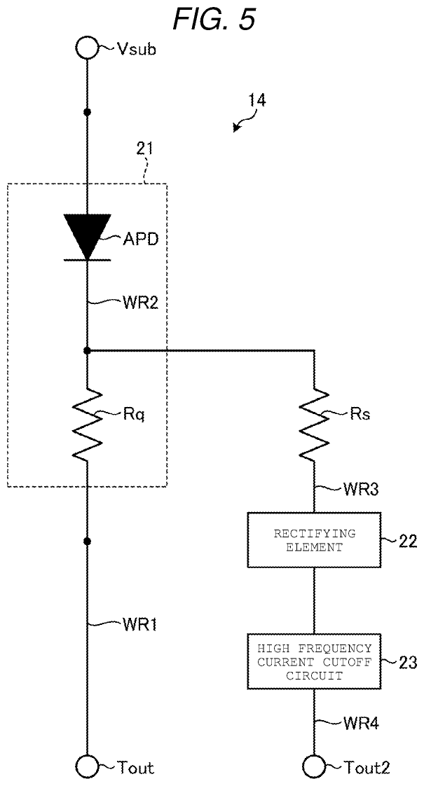

FIG. 5 is a circuit diagram of a SPAD in the light detector according to the first embodiment. In the first embodiment, the SPAD 21 constituting the light detector 14 includes an avalanche photodiode APD and a quenching resistor Rq having one end connected to a cathode of the avalanche photodiode APD and the other end connected to an output terminal Tout.

Further, a protective resistor Rs, a rectifying element (for example, a diode) 22, and a high-frequency current cutoff circuit 23 are connected in series to the cathode of the avalanche photodiode APD.

The output terminal of the high-frequency current cutoff circuit 23 is connected to a constant voltage source (voltage Vout2) via the output terminal Tout2. The voltage Vout2 is set to a potential higher than Vbd+Vth−Vov2.

In this case, an effective resistance value where the protective resistor Rs, the rectifying element 22, and the high-frequency current cutoff circuit 23 (conductive state) are added, is set to be smaller than a resistance value of the quenching resistor Rq.

Further, instead of the rectifying element 22, a capacitor may be mounted on the same semiconductor chip as the avalanche photodiode.

The high-frequency current cutoff circuit 23 can be configured with an inductor or a synchronous switch containing an inductor component of several nH to several tens of nH or more (for example, 10 nH or more). In this case, the inductor or the synchronous switch is effectively in the OFF state during the period in which the avalanche current, which is the high frequency current generated in the avalanche photodiode APD, flows, and the avalanche current is cut off.

A configuration example of the light detector will be described in detail.

In the present embodiment, the light detector 14 is configured as the silicon photo multiplier (SiPM).

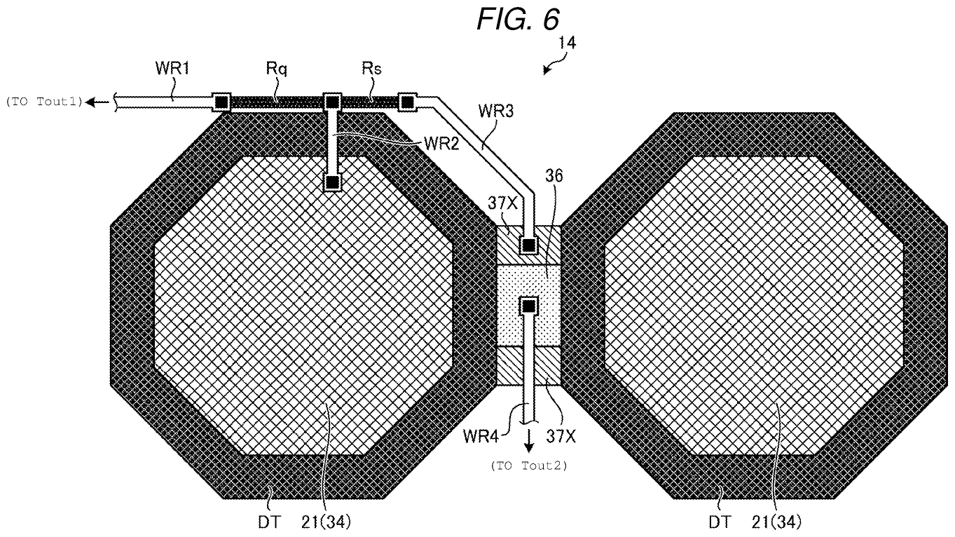

FIG. 6 illustrates a plan view of a part of an array of SPADs.

As illustrated in FIG. 6, the light detector 14 surrounds the periphery of each SPAD 21 with a deep trench DT to electrically separate the SPADs 21 from each other. The light detector 14 is specifically a silicon photo multiplier (SiPM).

The deep trench DT is an element separation structure formed by forming a deep groove (trench) of several micrometers on a silicon substrate and backfilling the groove with an insulator, or an insulator and a metal. Regarding the deep trench DT, it is possible to narrow the separation width to the processing accuracy of trench formation.

The deep trenches DT surrounding the adjacent SPAD 21 are separated from each other by a predetermined distance (for example, the shortest distance of 2 μm) according to the design rule, and a diode as a rectifying element 22 is formed in the separation part.

With this configuration, it is possible to arrange the maximum number of avalanche photodiodes APD without causing area loss due to diode formation.

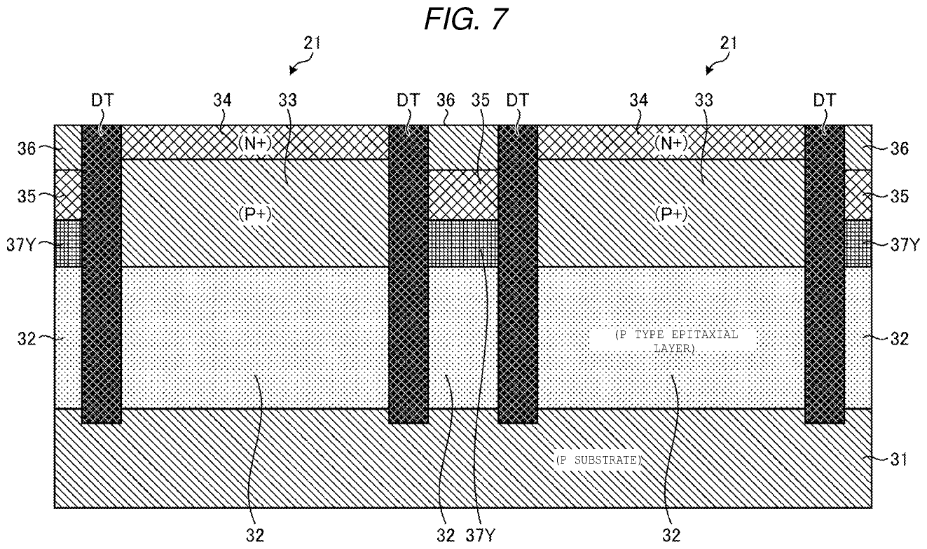

FIG. 7 illustrates a cross-sectional view of the part of the SPADs.

In the SPAD 21, P type epitaxial layers 32 are stacked on a P type silicon substrate 31. Ion-implanted P+ type layers 33 are stacked on the P type epitaxial layer 32.

N+ type layers 34 are stacked on the P+ type layer 33.

Further, the P type epitaxial layers 32 are stacked on the P type silicon substrate 31 between the deep trenches DT corresponding to the adjacent SPADs.

Ion-implanted N+ type layers 35 are stacked on the P type epitaxial layer 32.

The P+ type layers 36 are stacked on the N+ type layer 35 to form a diode as a rectifying element.

Further, below the N+ type layer 35, an N− type layer 37Y having a concentration lower than that of the N+ type layer 35 is disposed.

As illustrated in the plan view in FIG. 6, the P+ type layer 36 is in a state in which the periphery thereof is surrounded by a pair of deep trenches DT and the N+ type layer 35.

Further, the N+ type layer 35 is in a state of being in contact with the pair of deep trenches DT facing each other.

That is, the P+ type layer 36 (P type semiconductor constituting the diode) constituting the diode is surrounded by the trench DT and the N+ type layer 35 (N type semiconductor).

As a result, the P+ type layer 36 is separated from the P type epitaxial layer 32 and the P type silicon substrate 31.

At this time, for the diode, according to the design rule, by disposing the diode in an area between the trenches DT, which is the disabled area, it is possible to use the area as effectively as possible.

The P+ type layer constituting the diode is connected to the output terminal Tout2 with the wiring WR4.

On the other hand, an N+ type layer 37X constituting the diode is connected to one end of the protective resistor Rs via the wiring. The other end of the protective resistor Rs is connected to one end of the quenching resistor Rq and the N+ type layer constituting the SPAD via the wiring.

Further, the other end of the quenching resistor Rq is connected to the output terminal Tout via the wiring.

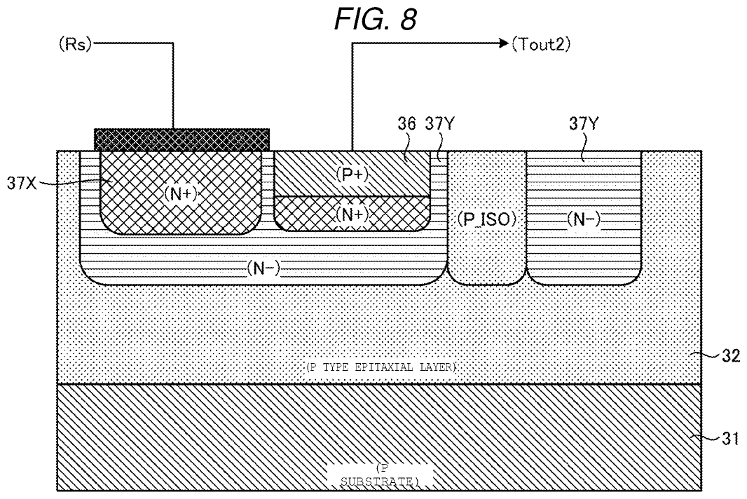

FIG. 8 illustrates another cross-sectional view of the diode in a cross section perpendicular to the cross section illustrated in FIG. 7.

P_ISO is a P+ type layer and is not necessarily required, but separates between the diodes when other diodes are laid out close together.

Next, the effect of the first embodiment will be described.

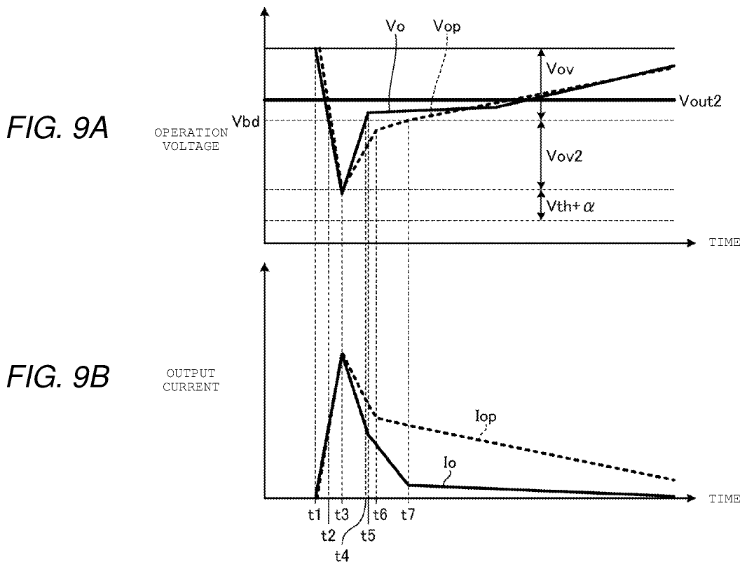

FIGS. 9A and 9B illustrate a change in the cathode voltage of the avalanche photodiode.

As illustrated in FIGS. 9A and 9B, when an operation voltage starts to decrease at time t1 and the bias voltage drops to the breakdown voltage Vbd at time t2, the Geiger mode ends.

Thereafter, when the cathode voltage further decreases and it reaches the cathode voltage=Vbd−Vov2 at time t3, the avalanche phenomenon is almost stopped. Since the current due to the avalanche phenomenon has a large high-speed frequency component and can hardly pass through the high-frequency current cutoff circuit 23, the current hardly increases up to time t3.

On the other hand, after time t3, the current is discharged via the diode as the rectifying element 22 and the high-frequency current cutoff circuit 23. Here, since the protective resistor Rs has a smaller resistance value than the quenching resistor Rq, the discharged current is large.

After time t3, the cathode voltage gradually recovers and becomes a state in which there is no carrier. At time t4, when the cathode voltage becomes equal to the breakdown voltage Vbd, the state shifts to the recovery state. The potential of the cathode of the avalanche photodiode exceeds Vout−Vth.

After the time t5, the current via the diode as the rectifying element 22 disappears, and the voltage decrease becomes gradual.

In contrast to this, in the comparative example, when the operation voltage starts to decrease at time t1 and the bias voltage drops lower than the breakdown voltage Vbd at time t2, the Geiger mode ends.

Thereafter, when the cathode voltage further decreases and it reaches the cathode voltage=Vbd−Vov2 at time t3, the avalanche phenomenon is also stopped.

As a result, the cathode voltage gradually recovers and enters a state in which there is no carrier, and recovers more slowly at time t6 (>t4).

At time t7, when the cathode voltage becomes equal to the breakdown voltage Vbd, the state shifts to the recovery state.

As described above, according to the present embodiment, the recovery time, which is the time from when the avalanche current is stopped until the voltage becomes higher than the breakdown voltage Vbd, is shortened. That is, the dead time is shortened and the next measurement can be performed sooner.

The output current demonstrates the profile as illustrated in FIG. 9B, and the gain of the output current Io of the embodiment is reduced with respect to the output current Iop of the comparative example, but the response is speeded up. Due to the speedup, the recovery time constant becomes smaller, and the number of photons that can be received by the SPAD per unit time (for example, 20 ns) increases.

For example, in the comparative example, when the recovery time constant of 10 ns is changed to 5 ns in the present embodiment, the number of photons that can be received per 10 ns is improved by substantially 2 times. This means that a dynamic range, which is an important issue for the SiPM, is improved by 2 times.

On the other hand, from the viewpoint of the dynamic range, the number of SPADs per SiPM can be halved. For example, if it is possible to make the laser emission angle/viewing angle half by making the size of the sensor half in the horizontal direction, it is possible to reduce the cost of silicon and improve the SN of the LiDAR by substantially 1.4 times.

According to the first embodiment, the period of the bias voltage drop can be shortened to reduce the residual output as shown below. Further, in this case, the high frequency current cutoff circuit reduces the current flowing to the constant power supply side when the avalanche phenomenon occurs, and thus the increase in crosstalk noise can be reduced because it does not interfere with the voltage drop due to the quenching resistor Rq.

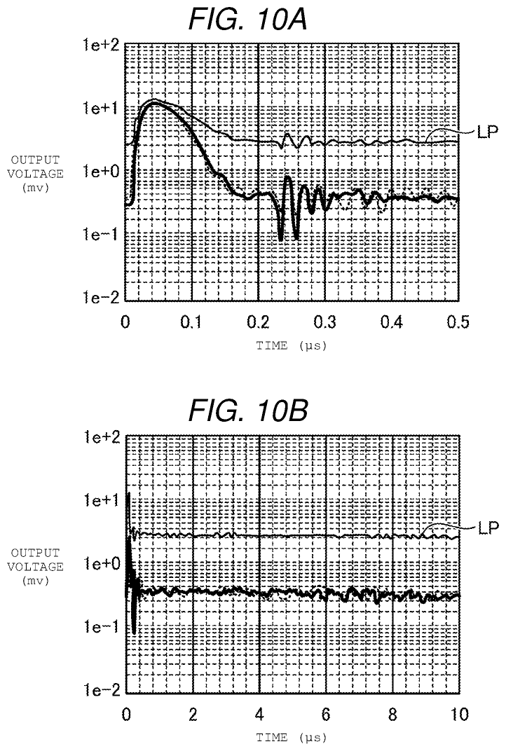

FIGS. 10A and 10B illustrate a measurement result of the residual output.

FIG. 10A illustrates the output voltage of the SPAD from the start of light reception to 0.5 μsec.

FIG. 10B illustrates the output voltage of the SPAD from the start of light reception to the emission time of 10 μsec.

FIGS. 10A and 10B illustrate a waveform LP of the comparative example, a waveform when the diode is enabled and a waveform when the diode is disabled, respectively.

As illustrated in FIG. 10B, the residual output is substantially 1/10 in the waveform when the diode is enabled as compared with the waveform LP of the comparative example. Therefore, it can be seen that the influence of the residual output can be sufficiently reduced.

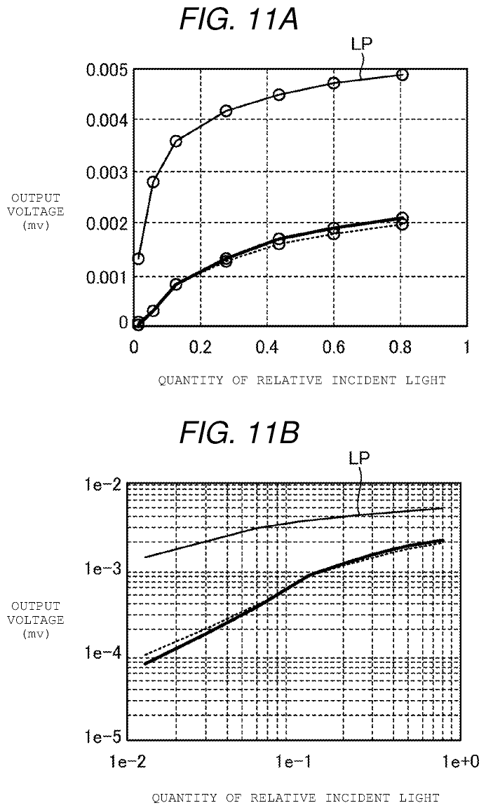

FIGS. 11A and 11B illustrate a quantity of relative incident light and an output voltage of a SPAD.

FIGS. 11A and 11B illustrate the quantity of relative incident light dependency of the output voltage when the diode is enabled and the quantity of relative incident light dependency of the output voltage when the diode is disabled, respectively.

As illustrated in FIGS. 11A and 11B, compared with the quantity of relative incident light dependency of the output voltage of the comparative example, in the quantity of relative incident light dependency of the output voltage when the diode is enabled, the residual output is reduced, and it can be seen that even when the quantity of light is small, there is a significant effect as compared with the comparative example.

It is considered that the reason why the residual output is small in the present embodiment is that the electrons in the SPAD are discharged quickly by the diode, and as a result, the electrons are hard to be accumulated.

### [1.1] First Modification Example of First Embodiment

Next, a first modification example of the first embodiment will be described.

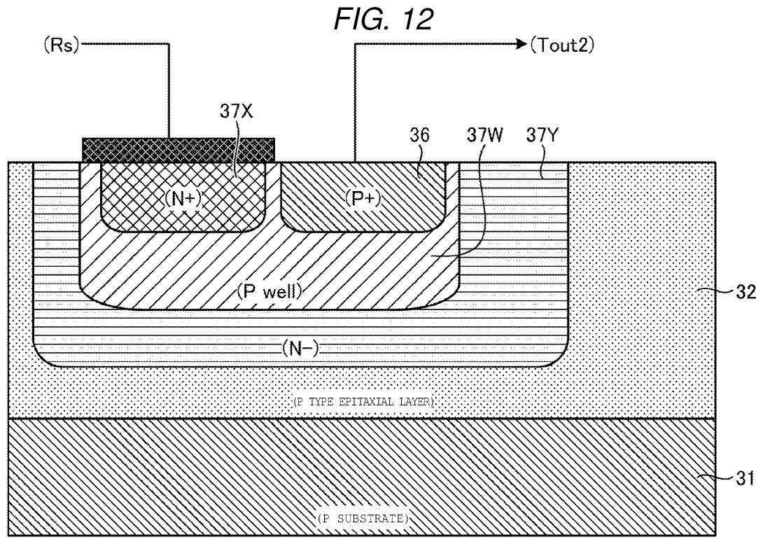

FIG. 12 is a cross-sectional diagram illustrating a part of the array of SPADs according to the first modification example of the first embodiment.

The diode as the rectifying element 22 of the first embodiment may have a cross-sectional structure as illustrated in FIG. 12.

The N+ type layer 37X and the P+ type layer 36 forming both ends of the diode are surrounded by the P well 37W which is a P type layer. Further, the P well 37W is surrounded by the N− type layer (Deep N well) 37Y.

The N− type layer 37Y is fixed to, for example, the VDD potential. Since the Dout is set to be equal to or lower than the VDD potential, the P well 37W is electrically cut off from the N− type layer 37Y and constitutes the diode together with the N+ type layer 37X and the P+ type layer 36.

In addition to the effect of the first embodiment, the effect of the first modification example of the first embodiment is that the N+ type layer 3X, P+ type layer 36, P well 37W, and N− type layer (deep N well) 37Y are a part of a CMOS process, and the CMOS process can be diverted to provide the diode without using a special layer.

### [1.2] Second Modification Example of First Embodiment

Subsequently, a second modification example of the first embodiment will be described.

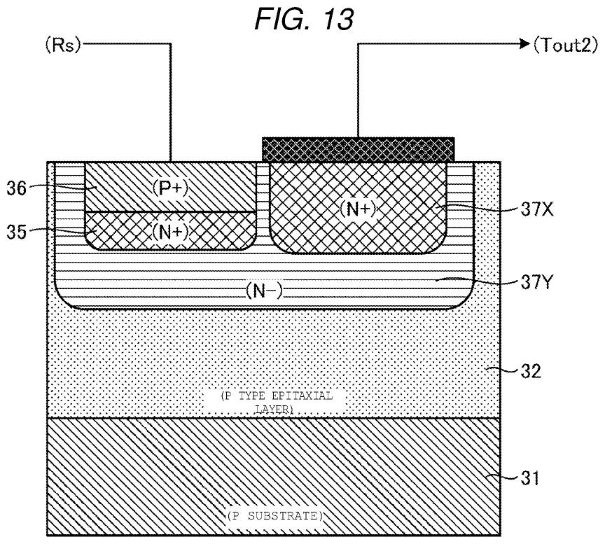

FIG. 13 is a cross-sectional diagram illustrating a part of an array of SPADs in the light detector according to the second modification example of the first embodiment.

The difference between the second modification example of the first embodiment and the first embodiment is that a Zener diode is used as the diode as the rectifying element 22.

The P+ type layer 36 constituting the diode is connected to one end of the protective resistor Rs by the wiring. On the other hand, the N+ type layer 37X constituting the diode is connected to the output terminal Tout2 via the wiring.

The Zener diode is connected with the opposite polarity to that of the first embodiment, and electrons are discharged from the cathode of the avalanche photodiode due to the current in the opposite direction. The threshold value thereof becomes the threshold value for generating the Zener current.

According to the second modification example, in addition to the effect of the first embodiment, the threshold value Vthz of the Zener diode can be larger than the threshold value Vthd of the diode of the first embodiment.

That is, when the appropriate value of the voltage Vout2 of the constant voltage source in the first embodiment is the voltage Vout2d, and when the threshold value thereof is set to Vthd−Vout2d, the voltage Vout2 in the second modification example becomes zero (GND), and the power supply for that purpose can be omitted. Further, since the potential of the terminal Tout is also near zero, it is possible to make the terminal Tout 2 and the terminal Tout common.

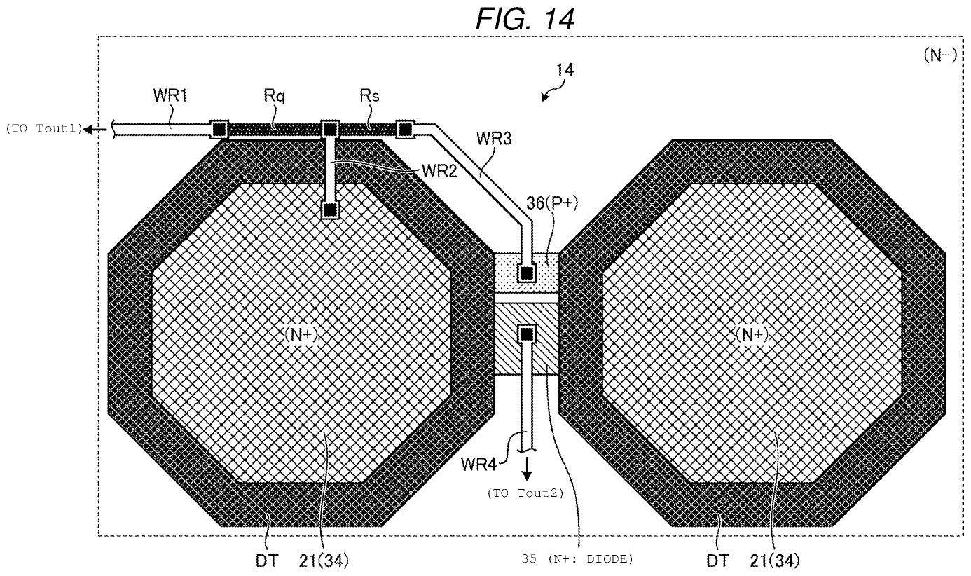

FIG. 14 illustrates a partial plan view of the part of the array of SPADs in the light detector according to the second modification example.

Further, the potential of the N− type layer 37Y is a voltage Vout2, which is common to all SPADs.

Therefore, as illustrated in FIG. 14, it is possible to completely fill the periphery of the SPAD with the N− type layer 37Y or the N+ type layer 37X (the P− type layer does not exist).

According to this configuration, all the potentials near the surface of the periphery of the SPAD are fixed at the potential of the voltage Vout2 of the constant voltage source.

By the way, since the N+ type layer 34 exists near the surface of the SPAD, when there is the P− type layer having a reverse bias potential Vsub at the periphery, an abnormal electric field concentration occurs between the two, and the breakdown voltage decreases.

Particularly, in order to provide high-performance SPAD, it is necessary to apply a large reverse bias, but due to the problem of a high electric field, it is not possible to apply a large reverse bias.

In contrast to this, according to the second modification example, since the periphery of the SPAD is fixed to the voltage Vout2, the abnormal electric field concentration and breakdown voltage decreasing do not occur.

Therefore, it is possible to apply a large reverse bias, and by extension, high-performance SPAD can be provided.

### [1.3] Third Modification Example of First Embodiment

Next, a third modification example of the first embodiment will be described.

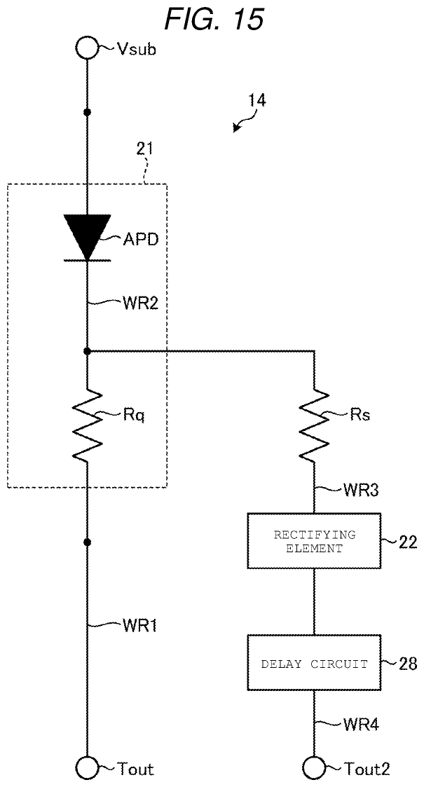

FIG. 15 is a circuit diagram of an SPAD in a light detector according to the third modification example of the first embodiment.

The difference between the third modification example and the first embodiment is that a delay circuit that causes a minute delay of 1 ns or less is connected as (instead of) the high-frequency current cutoff circuit 23.

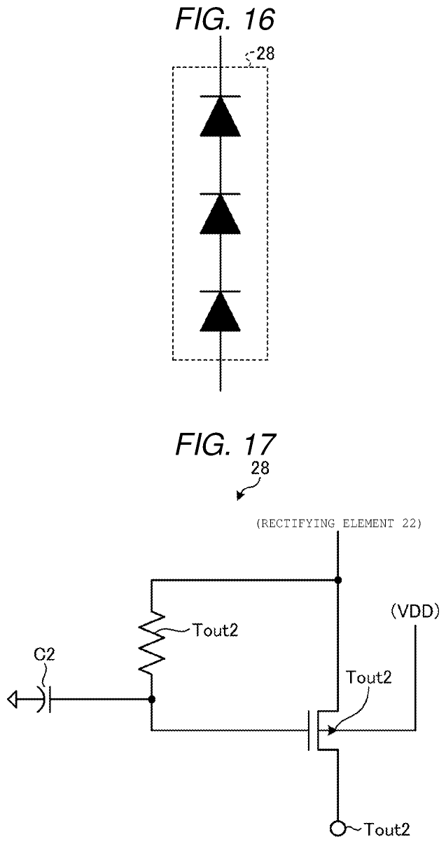

FIG. 16 is a circuit diagram of a delay circuit according to a first configuration example.

As the delay circuit, as illustrated in FIG. 16, for example, a plurality of the same diodes as the diodes constituting the rectifying element 22 are connected in series.

According to this configuration, a slight delay occurs when the diode is turned on, and as a result, the high frequency current becomes difficult to flow. This delay is generally (t3−t1) or more and equal to or less than the recovery time constant. For example, 30 ps or more and 5 ns or less is desirable.

FIG. 17 is a circuit diagram of a delay circuit according to a second configuration example.

Further, when a larger delay is required, as illustrated in FIG. 17, a gate that causes a delay may be used as the delay circuit 28.

In FIG. 17, the capacitance of the capacitor C2 is set to a minute value so that the high frequency current does not flow more than the desired value and the delay does not become too large.

Further, it is also possible to configure the circuits in FIGS. 16 and 7 to be combined.

According to the third modification example, in addition to the effect of the first embodiment, due to the delay of the delay circuit, the current that flows through the protective resistor Rs can be largely cut off until the time when the avalanche current almost stops, for example, the time t3 in FIG. 8.

Therefore, the operation of the avalanche photodiode is not adversely influenced. That is, the avalanche phenomenon does not become difficult to stop and the crosstalk noise does not increase due to the increasing of the avalanche current. On the other hand, by the subsequent discharging of the electrons, recovery is performed at high speed, and the residual output is kept small.

Further, the diode in FIG. 17 has the same configuration as the diode of the rectifying element 22 and can be implemented by the structure illustrated in FIGS. 6, 7, 12, and 13. Therefore, since it can be formed between the trenches DT of the SPAD adjacent to the rectifying element 22, there is no area loss and the manufacturing cost does not increase. In the case of FIG. 17, a PMOS transistor is required as a new element, but this can be easily implemented by adding an oxide film and a conductor on the P+ type layer 16 in FIG. 12 or FIG. 13.

### [2] Second Embodiment

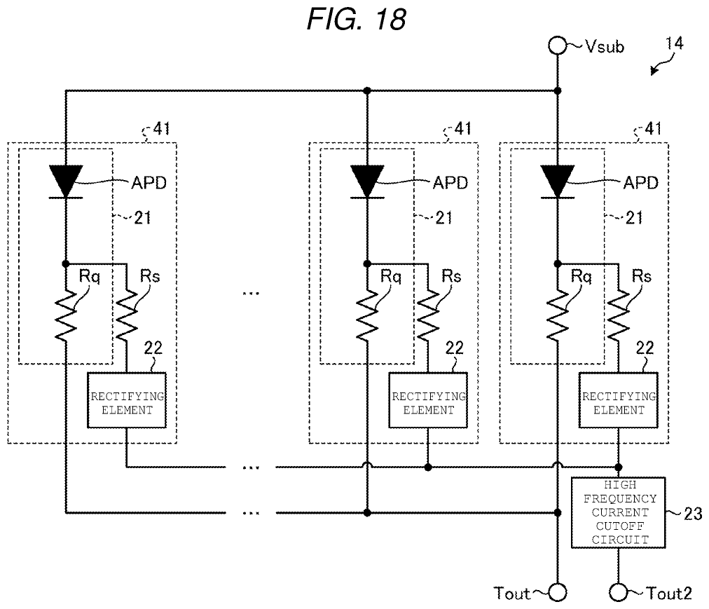

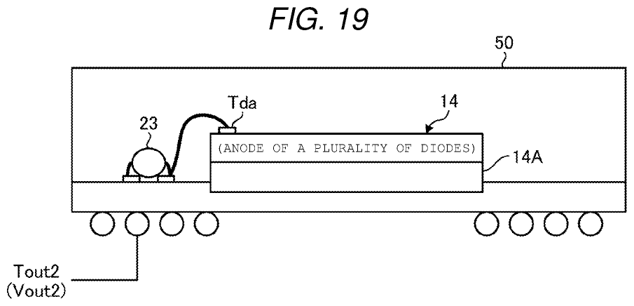

FIG. 18 is a circuit diagram of a light detector according to a second embodiment.

In FIG. 18, the same reference numerals are given to the same parts as in FIG. 5.

The difference between the second embodiment and the first embodiment is that a SPAD unit 41 is provided, in which the protective resistor Rs and the rectifying element (for example, a diode) 22 are connected to the SPAD 21, and one high-frequency current cutoff circuit 23 is provided for a plurality of SPAD units 41.

According to the second embodiment, it is possible to perform the same operation as that of the first embodiment, and it is possible to obtain the same effect as that of the first embodiment.

Further, since it is not necessary to provide the high-frequency current cutoff circuit 23 corresponding to each of the SPADs 21, the installation area of the light detector 14 can be further reduced.

### [2.1] First Modification Example of Second Embodiment

Next, a first modification example of the second embodiment will be described.

FIG. 19 illustrates a cross-sectional view of the light detector according to the first modification example of the second embodiment.

According to the first modification example of the second embodiment, as illustrated in FIG. 19, the high-frequency current cutoff circuit 23 (inductor) is provided outside a silicon chip 14A, not inside the silicon chip 14A of the light detector 14 so that the high frequency current cutoff circuit 23 is provided in the package 50 of the light detector 14.

One end of the high-frequency current cutoff circuit 23 (e.g., an inductor) is connected to a terminal Tda of a chip in which the anode outputs of the rectifying elements of a plurality of SPAD units 41 of the second embodiment are coupled via a bonding wire. The other end of the high-frequency current cutoff circuit 23 is connected to a pin or a solder ball through the wiring of the printed wiring substrate of the package and is connected to the outside power supply Tout2 (Vout2).

The effects of the first modification example of the second embodiment are as follows.

In general, it is difficult to manufacture a large inductor from silicon, and as in the present modification example, it is easier to manufacture by using a discrete element. By providing a large inductor, it becomes more difficult for high frequency current due to the avalanche phenomenon to pass through, and the potential of Dout2 can be set higher.

As a result, the effect of electron discharging becomes stronger, and the effect described in the first embodiment becomes enhanced. Further, by providing the inductor in the package of the light detector, it is possible to reduce the size of the device and simplify the design of the device.

Instead of being provided in the package of the light detector 14, the inductor may be mounted as a part of the outside power supply (Vout2). The effect thereof is the same as that of the present modification example.

### [2.2] Second Modification Example of Second Embodiment

Next, a second modification example of the second embodiment will be described.

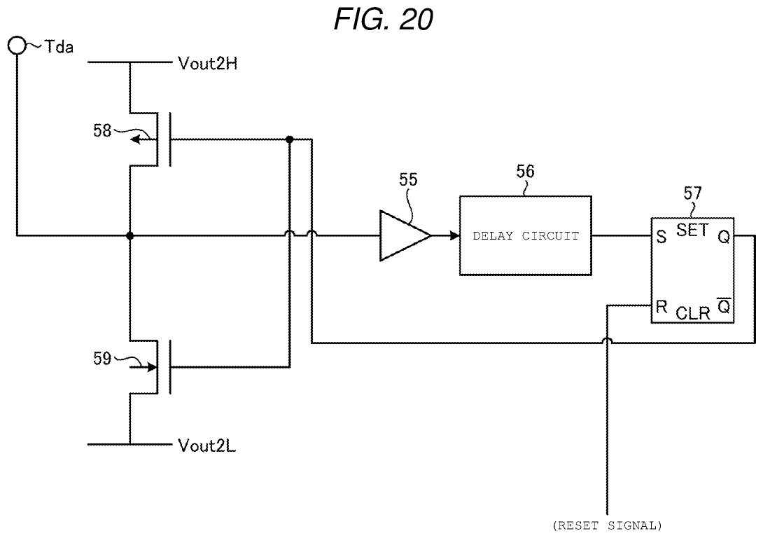

FIG. 20 is a circuit diagram of a high-frequency current cutoff circuit in a light detector according to the second modification example of the second embodiment.

In the second modification example of the second embodiment, as illustrated in FIG. 20, an input terminal of the delay circuit 56 is connected to the input terminal Tda, which couples the outputs of the rectifying elements of the plurality of SPAD units 41 of the second embodiment, via the sensing circuit 55. The output terminal of the delay circuit 56 is connected to a set terminal S of a negative logic RS flip-flop circuit 57.

Further, the input terminal Tda is connected to two switch elements having different polarities, for example, drains of the PMOS transistor 58 and the NMOS transistor 59. The constant power supply voltage Vout2 includes a relatively high potential voltage Vout2H (for example, voltage 0V) and a relatively low potential voltage Vout2L (for example, voltage−Vov[V]).

A source of the PMOS transistor 58 is connected to Vout2H, and a source of the NMOS transistor 59 is connected to Vout2L.

Further, a non-inverting output terminal Q of a flip-flop circuit 57 is connected to a gate of the PMOS transistor 58 and a gate of the NMOS transistor 59. An input signal of a reset terminal R of an RS flip-flop circuit 57 is given from the outside of the light detector.

A counter is used for the delay circuit 56. The delay time of the delay circuit 56 is adjusted to roughly match the round-trip time of the light having the maximum distance measuring distance. For example, when the maximum distance measuring distance is 100 m, the round-trip time of light is 667 ns. In the counters constituting the delay circuit 56, when it takes 5 ns for the first count, a count number is set such that it becomes 1 (“L” level) after 134 counts (=670 ns). It is assumed that the count number of the delay circuit 56 can be changed from the outside.

Subsequently, the operation of the second modification example of the second embodiment will be described.

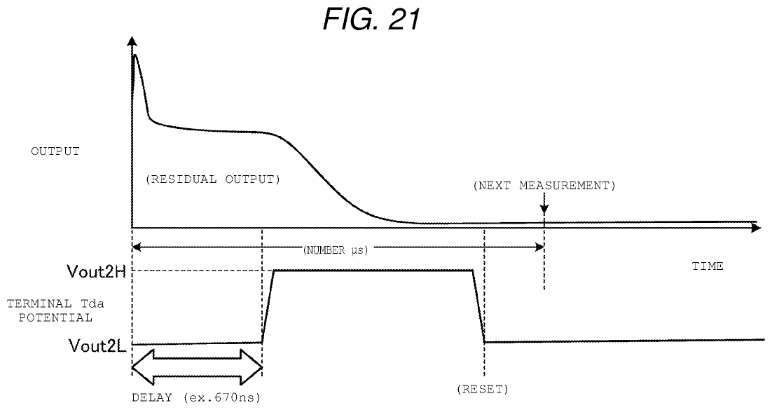

FIG. 21 illustrates a profile of a residual output in the second modification example of the second embodiment.

In the initial state, the non-inverting output terminal Q of the RS flip-flop circuit 57 is at the “H” level. Further, the PMOS transistor 58 is in the OFF state and the NMOS transistor 59 is in the ON state. As a result, the voltage Vout2L is applied to the anode of the diode as the rectifying element 22.

Therefore, even when the SPAD triggers, no current flows through the protective resistor Rs except when the voltage drop of the cathode thereof is significant. Therefore, as illustrated in FIG. 21, when the quantity of light is relatively large, the residual output may remain.

On the other hand, the sensing circuit 55 detects the voltage drop of the SPAD that triggers first after the emission of the laser light as the distance measurement light and outputs the detection signal at the “L” level.

After that, when the measurement is completed (substantially 667 ns after the laser light is emitted) and the delay circuit 56 transmits a signal, the non-inverting output terminal Q of the RS flip-flop circuit 57 is inverted to the “L” level. As a result, the state of the PMOS transistor 58 becomes ON, the state of the NMOS transistor 59 becomes OFF, and the Vout2 height is applied to the anodes of the diodes. The electrons are discharged through Rs, and as illustrated in FIG. 21, the residual output is kept low. Before the next measurement, a reset signal is transmitted from the outside, and the Q of the RS flip-flop returns to High. In the LiDAR, it is generally necessary to take a measurement interval of twice or more the round-trip distance of light having a maximum distance measuring distance, thereby in this way, the electrons are discharged each time measurement is performed. Further, due to the reset signal R, at the start of measurement, the state of the PMOS transistor 58 becomes surely OFF, and the influence of the current flowing through the protective resistor Rs on the measurement can be reduced.

By using the present modification example, the influence of electron discharging can be reduced during the distance measurement, and the electrons can be reliably discharged after the distance measurement.

### [2.3] Third Modification Example of Second Embodiment

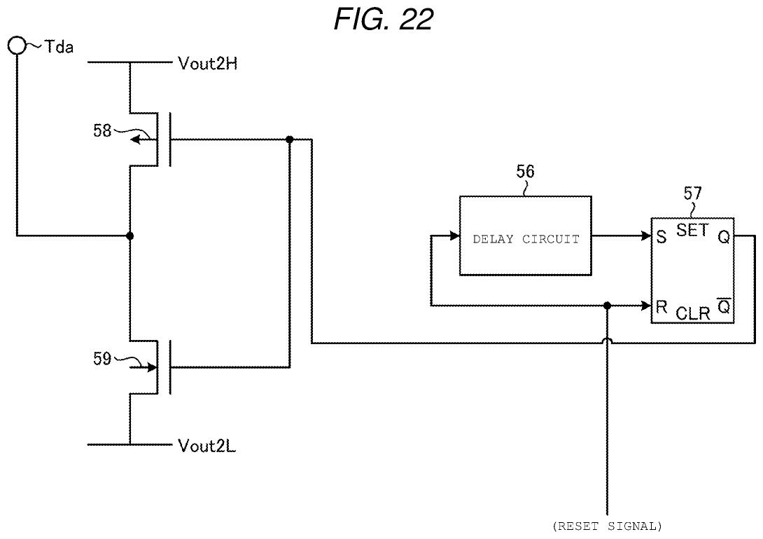

FIG. 22 is a circuit diagram of a high-frequency current cutoff circuit in a light detector according to a third modification example of the second embodiment.

In the present third modification example, instead of the sensing circuit 55 in the second modification example of the second embodiment illustrated in FIG. 20, the reset signal from the outside is connected to the input of the delay circuit 56.

Also in the present modification example, as in the second modification example of the second embodiment, the reset signal is transmitted from the outside immediately before the measurement. After 670 ns, that is, after the measurement is completed, the S terminal of the RS flip-flop becomes Low via the delay circuit. As a result, the state of the NMOS becomes OFF, the state of the PMOS becomes ON, and the voltage Vout2H is applied to the anodes of a plurality of diodes. The electrons are discharged through the protective resistor Rs, and as illustrated in FIG. 21, the residual output is kept low.

Also, in the third modification example of the second embodiment, the influence of electron discharging can be reduced during the distance measurement, and the electrons can be reliably discharged after the distance measurement. Further, due to the reset signal R, at the start of measurement, the state of the PMOS transistor 58 becomes surely OFF, and the influence of the current flowing through the protective resistor Rs on the measurement can be reduced.

For example, the following configuration is also possible.

A light detector that has a plurality of SPADs each having an avalanche photodiode and a quenching resistor of which one end is connected to the avalanche photodiode, including a rectifying element connected to a connection point between the avalanche photodiode and the quenching resistor via a protective resistor, and a first circuit that is connected between the rectifying element and a constant power supply and reduces a high frequency current flowing to a side of the constant power supply when an avalanche phenomenon occurs, and further including trenches that surround periphery of each of the avalanche photodiodes and are separated away from each other by a predetermined distance, in which the rectifying element may be separated from the corresponding avalanche photodiode by the trench, and the predetermined distance may be the shortest distance according to a design rule.

Further, a light detector that has a plurality of SPADs each having an avalanche photodiode and a quenching resistor of which one end is connected to the avalanche photodiode, including a rectifying element connected to a connection point between the avalanche photodiode and the quenching resistor via a protective resistor, and a first circuit that is connected between the rectifying element and a constant power supply and reduces a high frequency current flowing to a side of the constant power supply when an avalanche phenomenon occurs, in which a voltage of the constant power supply may be set lower than a potential of the other end of the quenching resistor.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A light detector, comprising:
an array of single-photon avalanche photodiodes (SPADs), each of the SPADs comprising:
an avalanche photodiode (APD);
a first resistor connected in series with the APD;
a second resistor connected to a node between the APD and the first resistor;
a rectifying element connected in series with the second resistor, the rectifying element being between the second resistor and a constant power source; and
a high-frequency current reduction circuit connected in series with the rectifying element, the high-frequency current reduction circuit being between the rectifying element and the constant power source and configured to reduce a high-frequency current flowing toward the constant power source when an avalanche phenomenon occurs in the APD.

2. The light detector according to claim 1, wherein the high-frequency current reduction circuit cuts off the high-frequency current toward the constant power source.

3. The light detector according to claim 1, wherein the high-frequency current reduction circuit includes a delay circuit.

4. The light detector according to claim 3, wherein the delay circuit includes a plurality of reverse-biased diodes connected in series.

5. The light detector according to claim 3, wherein the delay circuit includes:
a transistor connected to the rectifying element,
a resistor connected between the rectifying element and a gate of the transistor, and
a capacitor connected to a node between the gate and the resistor.

6. The light detector according to claim 1, wherein
the APD of each of the SPADs is formed on a silicon substrate and surrounded by a trench, and
the rectifying element of a first one of the SPADs is formed between the trench surrounding the APD of the first one of the SPADs and the trench surrounding the APD of a second one of the SPADs.

7. The light detector according to claim 6, wherein the rectifying element of the first one of the SPADs is in contact with the trench surrounding the APD of the first one of the SPADs and the trench surrounding the APD of the second one of the SPADs.

8. The light detector according to claim 1, wherein
the APD of each of the SPADs is formed on a silicon substrate and surrounded by a trench, and
the rectifying element of each of the SPADs comprises a diode including a P-type semiconductor layer surrounded by the trench and a N-type semiconductor layer.

9. A distance measurement device, comprising:
a light emitter configured to emit measurement light to a target;
a light detector according to claim 1, the light detector configured to receive measurement light reflected by the target; and
a measurement circuit configured to measure a distance to the target based on an emission time of the measurement light by the light emitter and a reception time of the measurement light by the light detector.

10. A light detector, comprising:
an array of single-photon avalanche photodiodes (SPADs), each of the SPADs comprising:
an avalanche photodiode (APD);
a first resistor connected in series with the APD;
a second resistor connected to a node between the APD and the first resistor; and
a rectifying element connected in series with the second resistor, the rectifying element being between the second resistor and a constant power source; and
a high-frequency current reduction circuit connected to the rectifying element of each of the SPADs, and configured to reduce a high-frequency current flowing therethrough when an avalanche phenomenon occurs in the APD of one or more of the SPADs.

11. The light detector according to claim 10, wherein the high-frequency current reduction circuit cuts off the high-frequency current.

12. The light detector according to claim 10, wherein the high-frequency current reduction circuit includes a delay circuit.

13. The light detector according to claim 10, wherein
the APD of each of the SPADs is formed on a silicon substrate and surrounded by a trench, and
the rectifying element of a first one of the SPADs is formed between the trench surrounding the APD of the first one of the SPADs and the trench surrounding the APD of a second one of the SPADs.

14. The light detector according to claim 13, wherein the rectifying element of the first one of the SPADs is in contact with the trench surrounding the APD of the first one of the SPADs and the trench surrounding the APD of the second one of the SPADs.

15. The light detector according to claim 10, wherein
the APD of each of the SPADs is formed on a silicon substrate and surrounded by a trench, and
the rectifying element of each of the SPADs comprises a diode including a P-type semiconductor layer surrounded by the trench and a N-type semiconductor layer.

16. The light detector according to claim 10, wherein
the array of SPADs is in a chip, and
the high-frequency current reduction circuit is outside the chip.

17. The light detector according to claim 10, wherein the high-frequency current reduction circuit includes:
a switch element connected to the rectifying element of each of the SPADs; and
a control circuit connected to a gate of the switch element and configured to turn the switch element on and off.

18. The light detector according to claim 17, wherein the control circuit is configured to turn off the switch element based on an output current from the APD of one or more of the SPADs, and turn on the switch element based on a reset signal input from an external circuit that is external to the light detector.

19. The light detector according to claim 17, wherein the control circuit is configured to turn off and on the switch element based on a reset signal input from an external circuit that is external to the light detector.

20. A distance measurement device comprising:
a light emitter configured to emit measurement light to a target;
a light detector according to claim 10, the light detector configured to receive measurement light reflected by the target; and
a measurement circuit configured to measure a distance to the target based on an emission time of the measurement light by the light emitter and a reception time of the measurement light by the light detector.
